(19) United States
(12) Patent Application Publication
(10) Pub. No.: US 2014/0218864 A1
(43) Pub. Date: Aug. 7, 2014

(54) ELECTRONIC DEVICE WITH COOLING ASSEMBLY

(71) Applicant: HON HAI PRECISION INDUSTRY CO., LTD., New Taipei (TW)

(72) Inventor: PEI-HSI WONG, New Taipei (TW)

(73) Assignee: HON HAI PRECISION INDUSTRY CO., LTD., New Taipei (TW)

(21) Appl. No.: 14/146,734

(22) Filed: Jan. 3, 2014

(30) Foreign Application Priority Data
Feb. 4, 2013 (TW) 102104146

(51) Int. Cl. H05K 7/20

(52) U.S. Cl. CPC H05K 7/20145; H05K 7/20445
USPC 361/697; 165/121; 165/109.1

(57) ABSTRACT

An electronic device includes a bottom plate and a cooling assembly. The cooling assembly includes an installation box, a fan received in the installation box, and a fin module secured to the installation box and closed to the fan. The fin module defines a cutout adjacent to the fan module and extends towards the bottom plate. An airflow directed by the fan is guided along a first direction by the fin module to dissipate heat generated from a heat generating component that is thermally connected to the fin module, and along a second direction through the cutout to dissipate heat generated from the bottom plate. The cooling assembly dissipates heat for the heat generating component and the bottom plate simultaneously.

### BACKGROUND

1. Technical Field

The present disclosure relates to electronic devices, and more particularly to an electronic device with a cooling assembly.

2. Description of Related Art

As electronic devices, such as notebook computers, become thinner from technology development. A plurality of fins is used in the notebook for dissipating heat generated by electronic component, such as Central Processing Unit (CPU). The plurality of fins abuts an enclosure of the notebook, which may increase temperature of the enclosure. To decrease the temperature, on the one hand, the height of the plurality of fins are reduced, which may reduce an area of each of plurality of fins to influence radiation efficiency of the electronic component, and on another hand, coppers or graphite sheets are pasted on the enclosure to dissipate heat of the enclosure, that may increase costs. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device in accordance with an embodiment.

FIG. 2 is an enlarged view of a circled portion II of the electronic device of FIG. 1.

FIG. 3 is similar to FIG. 1, but a baffle plate being secured to a fan module.

FIG. 4 is an assembled, isometric view of the electronic device of FIG. 1.

FIG. 5 is a cross-sectional view of the electronic device of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

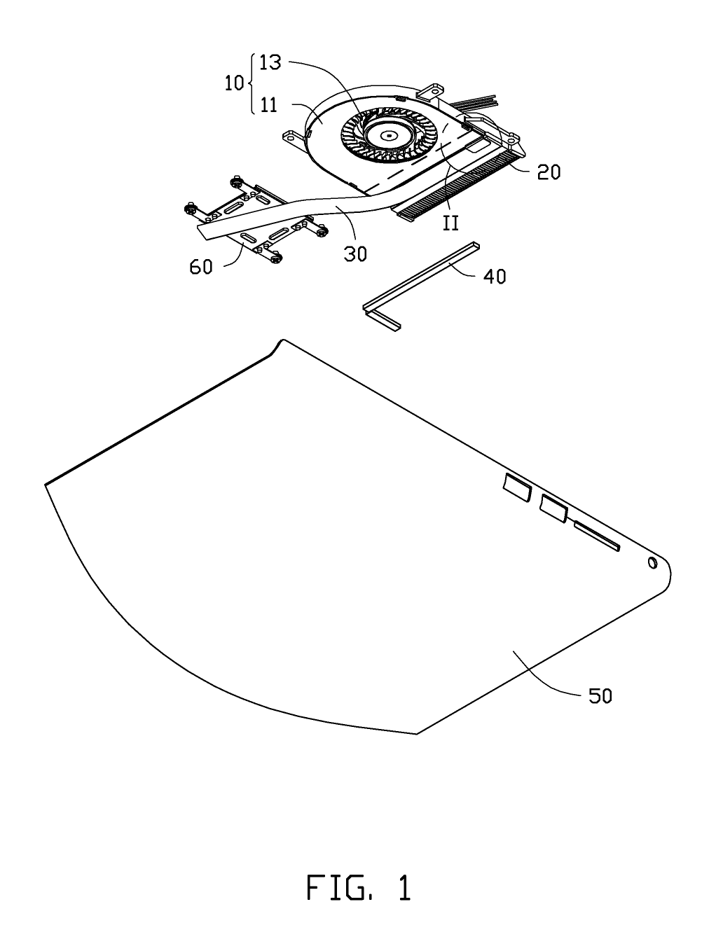

FIGS. 1-3 show one embodiment of an electronic device. The electronic device comprises a bottom plate 50 and a cooling assembly. The cooling assembly comprises a fan module 10, a fin module 20, a heat pipe 30, and a baffle plate 40. In one embodiment, the electronic device, may be a notebook computer, for example.

The fan module 10 comprises an installation box 11 attached to the bottom plate 50 and a fan 13 received in the installation box 11.

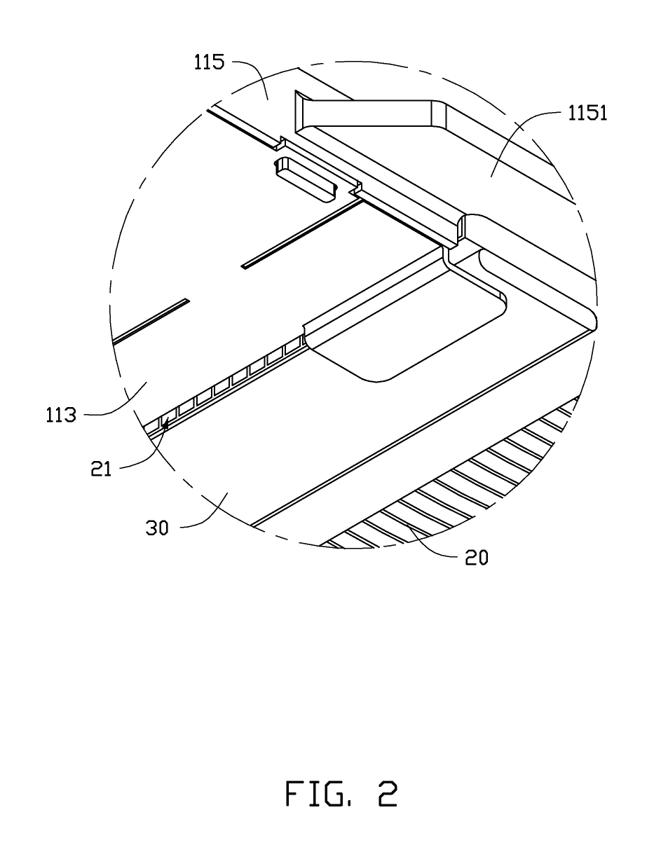

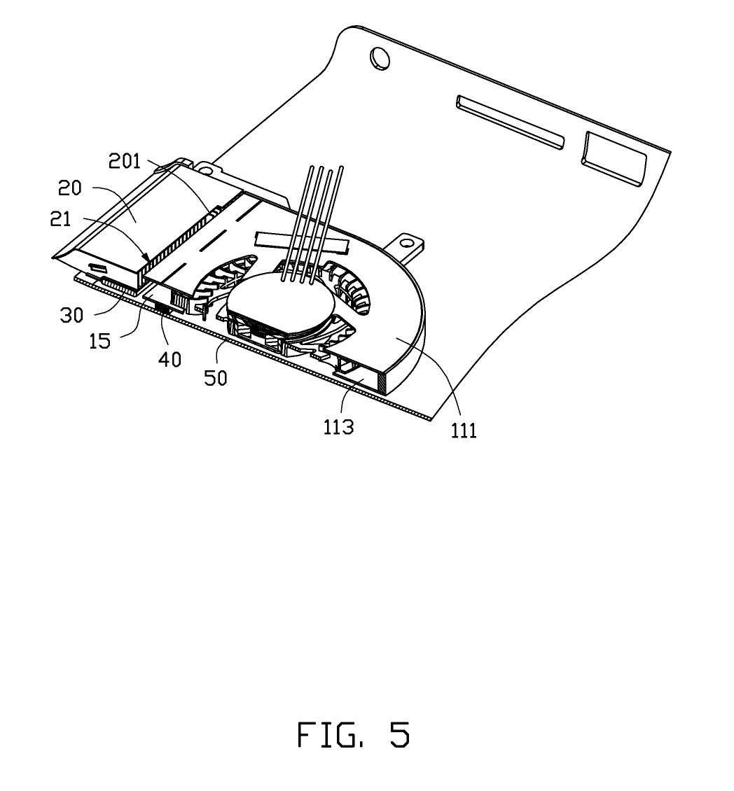

FIGS. 2 and 5 show that the installation box 11 defines an air outlet 15 and comprises a first installation plate 111, a second installation plate 113, and a connecting plate 115 connected to the first installation plate 111 and the second installation plate 113. In one embodiment, the first installation plate 111 is substantially parallel to the second installation plate 113. The fan 13 is secured between the first installation plate 111 and the second installation plate 113. The air outlet 15 is defined by the first installation plate 111 and the second installation plate 113. A plurality of securing pieces 1151 extend outwards from the connecting plate 115 for securing the fan module 10.

The fin module 20 is secured to the bottom plate 50 and comprises a plurality of fins 201. The fin module 20 defines an elongated cutout 21 in communication with an airflow passage of the fan 13. The cutout 21 extends downwards to a part of the plurality of fins 201 towards the bottom plate 50. A width of the cutout 21 is in a range from about 0.8 mm to about 3 mm. In one embodiment, the width of the cutout 21 is about 1 mm. A length of the cutout 21 is determined by a length of the second installation plate 113. In one embodiment, the length of the cutout 21 is about 10 mm.

One end of the pipe 30 is attached in the fin module 20, and the other end of the pipe 30 is attached to a heat sink 60. The heat sink 60 dissipates heat generated by one of heat generating components, such as CPU.

The baffle plate 40 is secured to the first installation plate 111 and arranged at two adjacent edges of the cutout 21, to prevent airflow from the fan 13 from back-flow. In one embodiment, the baffle plate 40 is substantially L-shaped and made of sponge. A width of the baffle plate 40 is about 2 mm to about 4 mm and a length of the baffle plate 40 is changeable according to the length of the cutout 21. In one embodiment, the width of the baffle plate 40 is about 3 mm, and the length of the baffle plate 40 is longer than the length of the cutout 21.

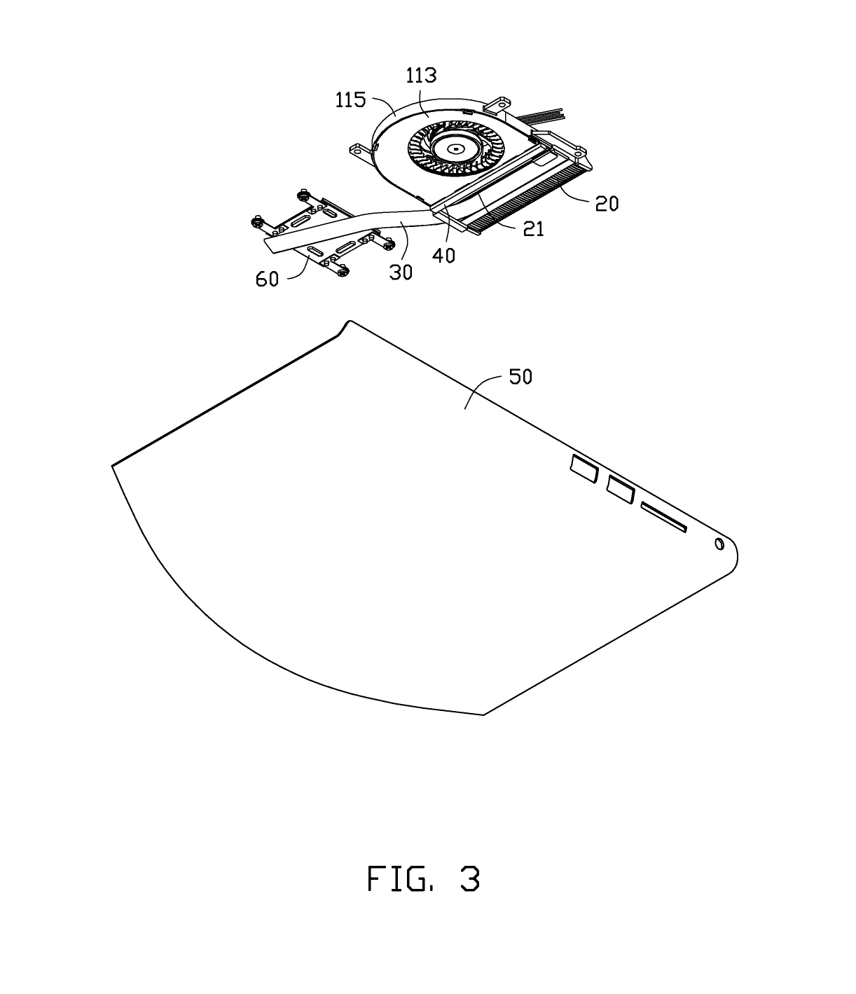

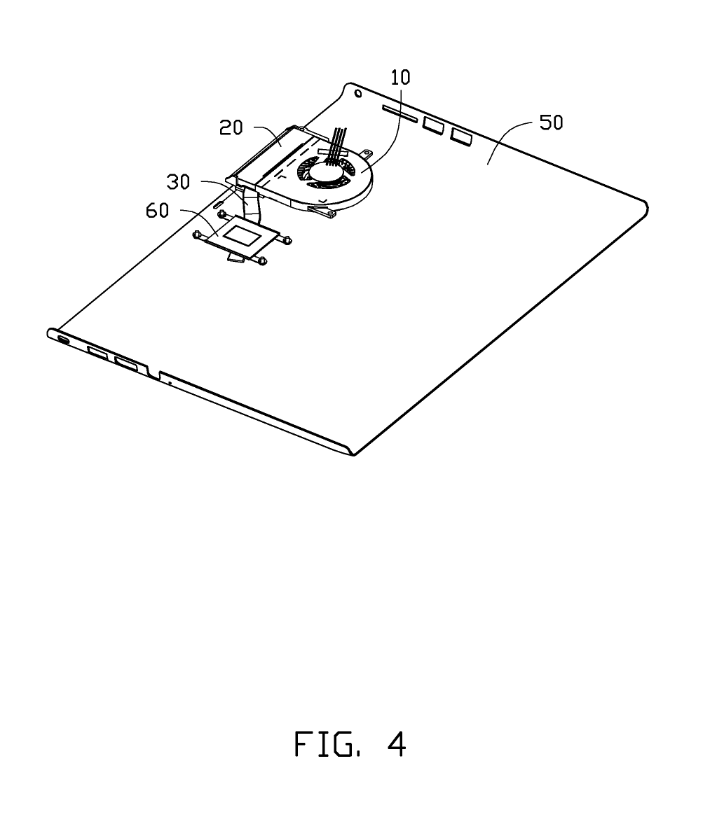

FIGS. 3-5 illustrate an assembled view of the electronic device in accordance with an embodiment. In assembly, the cooling assembly is attached to the bottom plate 50. The cutout 21 faces the air outlet 15 and communicates with the air outlet 15. The baffle plate 40 is located between the bottom plate 50 and the first installation plate 111. A thickness of the baffle plate 40 is substantially equal to a distance between the first installation plate 111 and the bottom plate 50.

In use, the fan 13 generates an airflow along a first direction through the air outlet 15 to dissipate heat generated by the heat generating component, and along a second direction through the cutout 21 to dissipate heat generated by the bottom plate 50. The first direction is substantially perpendicular to the second direction.

The cooling assembly not only dissipates heat from the heat generating component, but also dissipates heat from the bottom plate 50.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a bottom plate; and
a cooling assembly comprising:
a fan module comprises an installation box attached to the bottom plate and a fan received in the installation box; and
a fin module secured to a side of the fan module and closed to the installation box;
wherein the fin module defines a cutout adjacent to the fan module, and the cutout extends towards to the bottom plate; an airflow directed by the fan is guided along a first direction by the fin module, to dissipate heat generated from a heat generating component that is thermally connected to the fin module, and along a second direction through the cutout to dissipate heat from the bottom plate; and the second direction is substantially perpendicular to the first direction.

2. The electronic device of claim 1, the fin module comprises a plurality of fins, and the cutout is located between the fan and the plurality of fins.

3. The electronic device of claim 1, wherein the installation box defines an air outlet, which faces to the plurality of fins and the cutout.

4. The electronic device of claim 1, further comprising a baffle plate, wherein the baffle plate is secured to the installation box and arranged at two adjacent edges of the cutout, to prevent the airflow from backflow.

5. The electronic device of claim 4, wherein the installation box comprises a first installation plate, and the baffle plate is located between the bottom plate and the first installation plate.

6. The electronic device of claim 5, wherein the installation box further comprises a second installation plate substantially parallel to the first installation plate, and the fan is received between the first installation plate and the second installation plate.

7. The electronic device of claim 4, wherein a width of the baffle plate is about 2 mm to about 4 mm.

8. The electronic device of claim 7, wherein the width of the baffle plate is about 3 mm.

9. The electronic device of claim 4, wherein a length of the baffle plate is greater than a length of the cutout.

10. The electronic device of claim 9, wherein a width of the cutout is about 0.8 mm to about 3 mm.

11. A cooling assembly comprising:
a fan module comprises an installation box and a fan received in the installation box; and
a fin module secured to a side of the fan module and closed to the installation box;
wherein the fin module defines a cutout adjacent to the fan module, and the cutout extends towards the bottom plate; the fan module defines an air outlet communicating with the cutout; a first air path, along a first direction, is defined by the fan module, the air outlet, and the fin module, to dissipate heat generated from a heat generating component that is thermally connected to the fin module; a second air path, along a second direction, is defined by the fan module, the air outlet, and the cutout to dissipate heat generated from the bottom plate; and the second direction is substantially perpendicular to the first direction.

12. The cooling assembly of claim 11, the fin module comprises a plurality of fins, and the cutout is located between the fan and the plurality of fins.

13. The cooling assembly of claim 11, further comprising a baffle plate, wherein the baffle plate is secured to the installation box and arranged at two adjacent edges of the cutout, to prevent the airflow from backflow.

14. The cooling assembly of claim 13, wherein the installation box comprises a first installation plate, and the baffle plate is located between the bottom plate and the first installation plate.

15. The cooling assembly of claim 14, wherein the installation box further comprises a second installation plate substantially parallel to the first installation plate, and the fan is received between the first installation plate and the second installation plate.

16. The cooling assembly of claim 13, wherein a width of the baffle plate is about 2 mm to about 4 mm.

17. The cooling assembly of claim 16, wherein the width of the baffle plate is about 3 mm.

18. The cooling assembly of claim 13, wherein a length of the baffle plate is greater than a length of the cutout.

19. The cooling assembly of claim 18, wherein a width of the cutout is about 0.8 mm to about 3 mm.

20. The cooling assembly of claim 19, wherein the width of the cutout is about 1 mm.
